(19) United States
(12) Patent Application Publication
(10) Pub. No.: US 2014/0211401 A1
(43) Pub. Date: Jul. 31, 2014

(54) FIXING MECHANISM FOR FIXING A STORAGE MODULE OF AN ELECTRONIC DEVICE AND ELECTRONIC DEVICE THEREWITH

(71) Applicant: SYNOLOGY INCORPORATED, Taipei (TW)

(72) Inventors: Guo-Shiang Lee, New Taipei City (TW); Ming-Hung Tsai, New Taipei City (TW)

(73) Assignee: Synology Incorporated, Taipei (TW)

(21) Appl. No.: 13/862,483

(22) Filed: Apr. 15, 2013

(30) Foreign Application Priority Data
Jan. 31, 2013 (TW) 102103793

(51) Int. Cl. G06F 1/16; H05K 7/14

(52) U.S. Cl. CPC G06F 1/16; H05K 7/1418
USPC 361/679.31; 312/223.2

(57) ABSTRACT

A fixing mechanism for fixing a storage module of an electronic device includes a tray, two fixing components, two engaging structures and two fixing structures. The tray is for supporting the storage module. The two fixing components are detachably installed on two sides of the tray respectively. The two engaging structures are disposed on the two fixing components respectively, and the two engaging structures are for engaging the two fixing components with the tray. The two fixing structures are disposed on the two fixing components respectively, and two fixing structures are for fixing the storage module on the tray after the two fixing components are engaged with the tray.

### BACKGROUND OF THE INVENTION

1. Field of the Invention

The present invention relates to a fixing mechanism for fixing a storage module of an electronic device, and more specifically, to a fixing mechanism for fixing a storage module of an electronic device without using any screw.

2. Description of the Prior Art

A server computer is widely used in large enterprises, such as banks, game companies and technology companies. Most of normal server computers have different replaceable storage modules, such as a hard drive, for storing a lot of information. In order to facilitate a user to replace a new hard drive, tracks are often disposed on a casing of the server computer in the market, and sliding components corresponding to the tracks are installed on two sides of the hard drive, so that the hard drive can be slidably installed inside the casing of the server computer. However, the sliding components are often installed on the two sides of the hard drive by using screws, so that it does not facilitate the user to detach the sliding components from the hard drive and wastes too much time. As a result, it is an important issue to design a fixing mechanism of the storage module with easy assembly and without using any screw.

### SUMMARY OF THE INVENTION

The present invention is to provide a fixing mechanism for fixing a storage module of an electronic device without using any screw to solve above problems.

According to the disclosure, a fixing mechanism for fixing a storage module of an electronic device includes a tray, two fixing components, two engaging structures and two fixing structures. The tray is for supporting the storage module. The two fixing components are detachably installed on two sides of the tray respectively. The two engaging structures are disposed on the two fixing components respectively, and the two engaging structures are for engaging the two fixing components with the tray. The two fixing structures are disposed on the two fixing components respectively, and two fixing structures are for fixing the storage module on the tray after the two fixing components are engaged with the tray.

According to the disclosure, each fixing structure includes a front fixing portion, a middle fixing portion and a rear fixing portion for passing through a front hole, a middle hole and a rear hole respectively after the corresponding fixing component is engaged with the tray, to insert into a plurality of fixing holes on the storage module, so as to fix the storage module on the tray.

According to the disclosure, each engaging structure includes a front engaging portion and a rear engaging portion, and the front engaging portion and the rear engaging portion are engaged with a front engaging slot and a rear engaging slot of the tray respectively.

According to the disclosure, the front hole and the rear hole are communicated to the front engaging slot and the rear engaging slot respectively.

According to the disclosure, the middle fixing portion is a column whereon a slot is formed, and a size of the middle fixing portion is greater than a size of the corresponding fixing hole on the storage module, so that the middle fixing portion is deformed to engage with the storage module after passing through the corresponding fixing hole of the storage module.

According to the disclosure, the front engaging portion and the rear engaging portion are hooks, respectively.

According to the disclosure, at least one locating column is disposed on the tray for inserting into at least one locating hole on the storage module, so that the plurality of fixing holes is aligned to the corresponding front hole, the corresponding middle hole and the corresponding rear hole.

According to the disclosure, the front fixing portion, the middle fixing portion and the rear fixing portion are pins, respectively.

According to the disclosure, the fixing mechanism further includes four resilient components respectively disposed between the tray and the two fixing components, the four resilient components being respectively installed in the two front holes and the two rear holes, and the four resilient components being for contacting against the storage module to absorb shocks generated by the storage module as the two fixing structures fix the storage module on the tray.

According to the disclosure, each resilient component includes a groove, an inner portion and an outer portion, the four grooves of the four resilient components are engaged with the two front holes and the two rear holes respectively, and the four inner portions and the four outer portions of the four resilient components are located on two sides of the two front holes and the two rear holes respectively as the four grooves of the four resilient components are engaged with the two front holes and the two rear holes respectively, so as to contact against the two fixing components and the storage module respectively.

According to the disclosure, each engaging structure includes at least one protrusion, at least one opening is formed on the tray, and the at least one protrusion is engaged with the at least one opening, so that the corresponding fixing component is engaged with the tray.

According to the disclosure, each fixing component includes a detaching portion for driving the corresponding engaging structure to detach from the tray and driving the corresponding fixing structure to detach from the storage module and the tray as the detaching portion is forced.

According to the disclosure, an electronic device includes a casing whereon a track is disposed, an engaging component, a storage module and a fixing mechanism. The engaging component is disposed on a front end of the track. The storage module is installed inside the casing in a slidable manner relative to the track. The fixing mechanism for fixing the storage module of the electronic device includes a tray, two fixing components, two engaging structures and two fixing structures. The tray is for supporting the storage module. The two fixing components are detachably installed on two sides of the tray respectively. The two engaging structures are disposed on the two fixing components respectively, and the two engaging structures are for engaging the two fixing components with the tray. The two fixing structures are disposed on the two fixing components respectively, and two fixing structures are for fixing the storage module on the tray after the two fixing components are engaged with the tray.

The present invention provides the fixing mechanism for fixing the storage module on the tray. The front engaging portion and the rear engaging portion of the fixing component are respectively fixed on the front engaging slot and the rear engaging slot, and the front fixing portion, the middle fixing portion and the rear fixing portion of each fixing component respectively insert into the corresponding fixing holes of the storage module at the same time, so that the storage module is installed on the fixing mechanism. As a result, it improves the inconvenience in assembly by using the screws and the need of additional assembly tools, such as a screwdriver, to fix the storage module in the prior art. Therefore, the fixing mechanism of the present invention has enhanced convenience of assembly and has no additional manufacturing cost resulted from a complicated structural design. In addition, the fixing component is detachably installed on the tray, so that it can replace a new fixing component directly instead of replacing the whole fixing mechanism as the fixing component, the engaging structure or the fixing structure is damaged, so as to save the cost of components. Furthermore, as the storage module is detached from the tray, the fixing component and the resilient component can be installed on the tray again, so as to prevent the components from loss.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an electronic device according to an embodiment of the present invention.

FIG. 2 is an exploded diagram of a fixing mechanism according to the embodiment of the present invention.

FIG. 3 is an assembly diagram of the fixing mechanism according to the embodiment of the present invention.

FIG. 4 is a diagram of a storage module according to the embodiment of the present invention.

FIG. 5 is a diagram of a resilient component according to the embodiment of the present invention.

FIG. 6 is an assembly diagram of the storage module installed on the fixing mechanism according to the embodiment of the present invention.

### DETAILED DESCRIPTION

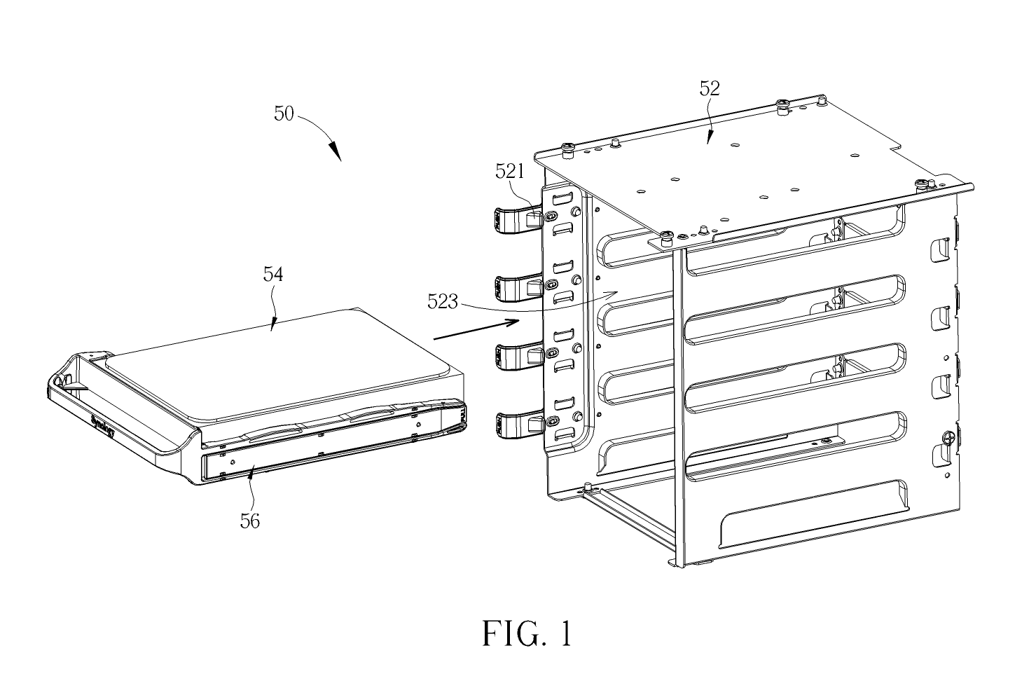

Please refer to FIG. 1. FIG. 1 is a diagram of an electronic device 50 according to an embodiment of the present invention. The electronic device 50 can be a desktop computer or a business server computer. The electronic device 50 includes a casing 52, at least one engaging component 521, a storage module 54 and a fixing mechanism 56. At least one track 523 is disposed on the casing 52, and the engaging component 521 is disposed on a front end of the corresponding track 523. In this embodiment, the casing 52 includes four engaging components 521 and four tracks 523, so as to facilitate a user to install a plurality of the storage modules 54 inside the casing 52. Amounts and positions of the engaging components 521 and the tracks 523 are not limited to this embodiment, and it depends on practical design demands. The storage module 54 is installed inside the casing 52 in a slidable manner relative to the track 523. The storage module 54 can be a hard drive for storing information. The fixing mechanism 56 is for supporting the storage module 54 and engaging with the engaging component 521 after the storage module 54 is installed inside the casing completely, so as to fix the storage module 54 inside the casing 52.

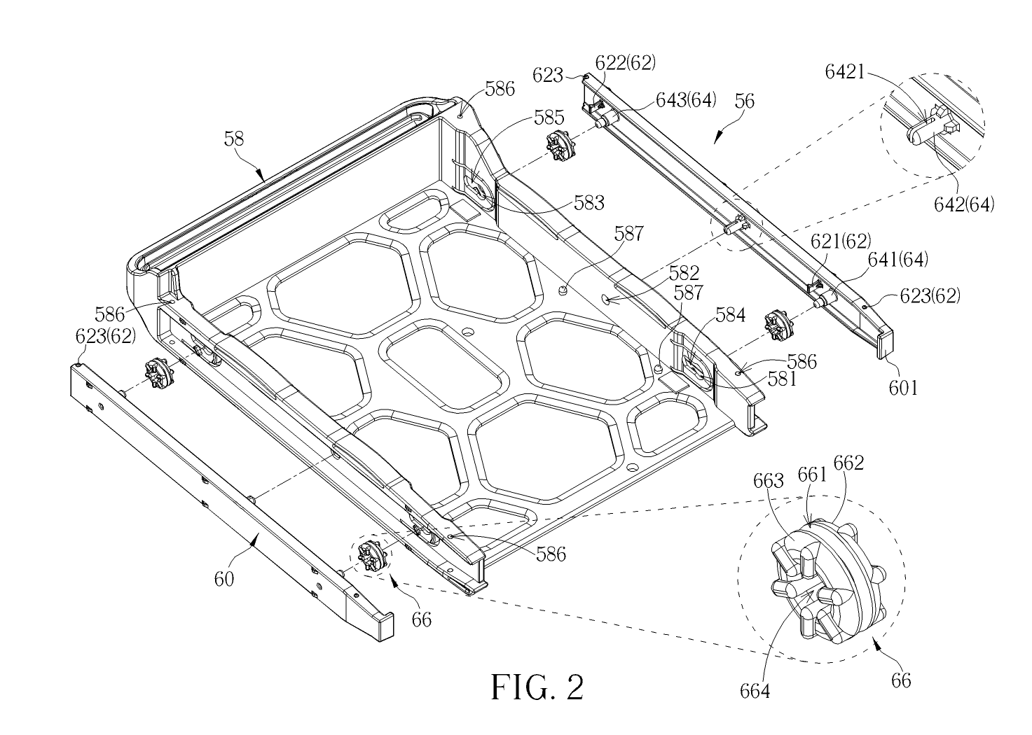

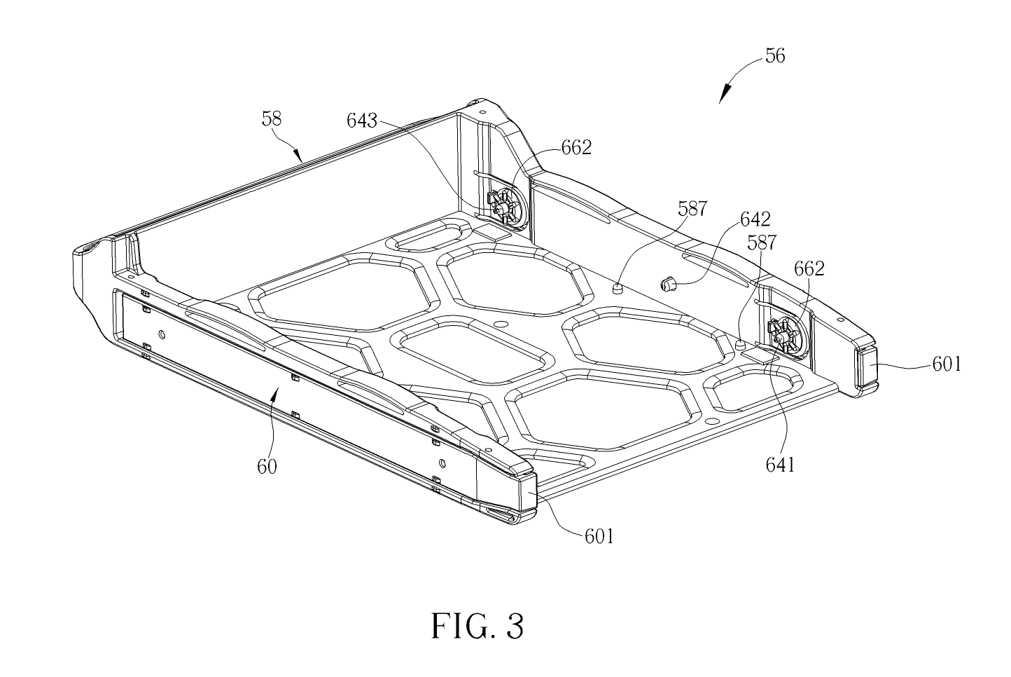

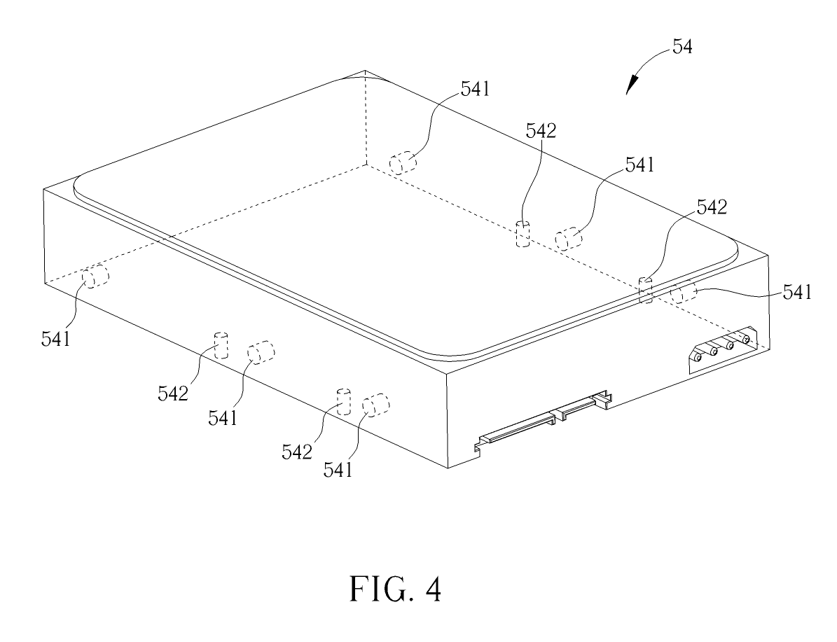

Please refer to FIG. 2 to FIG. 4. FIG. 2 is an exploded diagram of the fixing mechanism 56 according to the embodiment of the present invention. FIG. 3 is an assembly diagram of the fixing mechanism 56 according to the embodiment of the present invention. FIG. 4 is a diagram of the storage module 54 according to the embodiment of the present invention. The fixing mechanism 56 includes a tray 58, two fixing components 60, two engaging structures 62 and two fixing structures 64. The tray 58 is for supporting the storage module 54, and the two fixing components 60 are detachably installed on two sides of the tray 58 respectively. The two engaging structures 62 are disposed on the two fixing components 60 respectively, and the two engaging structures 62 are for engaging the two fixing components 60 with the tray 58. The two fixing structures 64 are disposed on the two fixing components 60 respectively, and the two fixing structures 64 are for fixing the storage module 54 on the tray 58 after the two fixing components 60 are engaged with the tray 58.

Each fixing structure 64 includes a front fixing portion 641, a middle fixing portion 642 and a rear fixing portion 643 for passing through a front hole 581, a middle hole 582 and a rear hole 583 respectively after the corresponding fixing component 60 is engaged with the tray 58, to insert into a plurality of fixing holes 541 on the storage module 54, so as to fix the storage module 54 on the tray 58. The front fixing portion 641, the middle fixing portion 642 and the rear fixing portion 643 can be pins, respectively. In addition, the middle fixing portion 642 can be a column whereon a slot 6421 is formed, so as to reduce structural rigidity thereof. A size of the column of the middle fixing portion 642 can be designed to be greater than a size of the corresponding fixing hole 541 of the storage module 54, so that the middle fixing portion 642 is deformed to engage with the storage module 54 after passing through the middle hole 582 to insert into the corresponding fixing hole of the storage module 54. Each engaging structure 62 includes a front engaging portion 621 and a rear engaging portion 622, and the front engaging portion 621 and the rear engaging portion 622 are engaged with a front engaging slot 584 and a rear engaging slot 585 of the tray 58 respectively. The front engaging portion 621 and the rear engaging portion 622 are hooks. The front hole 581 and the rear hole 583 are communicated to the front engaging slot 584 and the rear engaging slot 585 respectively. Furthermore, each engaging structure 62 includes at least one protrusion 623, and at least one opening 586 is formed on the tray 58. The at least one protrusion 623 is engaged with the at least one opening 586, so that the corresponding fixing component 60 is engaged with the tray 58. In this embodiment, each engaging structure 62 includes the two protrusions 623 for engaging with the corresponding two openings 586, respectively. Amounts and positions of the protrusions 623 and the openings 586 are not limited to this embodiment, and it depends on practical design demands.

Please refer to FIG. 2 and FIG. 4. at least one locating column 587 is disposed on the tray 58 for inserting into at least one locating hole 542 on the storage module 54, so as to locate the storage module 54, so that the plurality of fixing holes 541 is aligned to the corresponding front holes 581, the corresponding middle holes 582 and the corresponding rear holes 583. In this embodiment, four locating columns 587 (not shown in some figures) are disposed on the tray 58, and the storage module 54 includes four locating holes 542 and six fixing holes 541. Amounts and positions of the locating columns 587, the locating holes 542 and the fixing holes 541 are not limited to this embodiment, and it depends on practical design demands. In addition, the electronic device 50 of the present invention further includes four resilient components 66 respectively disposed between the tray 58 and the two fixing components 60, and the four resilient components 66 are respectively installed in the two front holes 581 and the two rear holes 583. The four resilient components 66 are for contacting against the storage module 54 to absorb shocks generated by the storage module 54 as the two fixing structures 64 fix the storage module 54 on the tray 58. Amount and position of the resilient component 66 are not limited to this embodiment, and it depends on practical design demands.

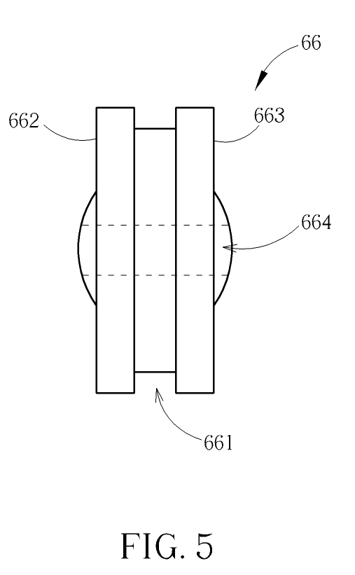

Please refer to FIG. 2 and FIG. 5. FIG. 5 is a diagram of the resilient component 66 according to the embodiment of the present invention. Each resilient component 66 includes a groove 661, an inner portion 662 and an outer portion 663, and the four grooves 661 of the four resilient components 66 are engaged with the two front holes 581 and the two rear holes 583, respectively. The four inner portions 662 and the four outer portions 663 of the four resilient components 66 are located on two sides of the two front holes 581 and the two rear holes 583 respectively as the four grooves 661 of the four resilient components 66 are respectively engaged with the two front holes 581 and the two rear holes 583, so as to contact against the two fixing components 60 and the storage module 54, respectively.

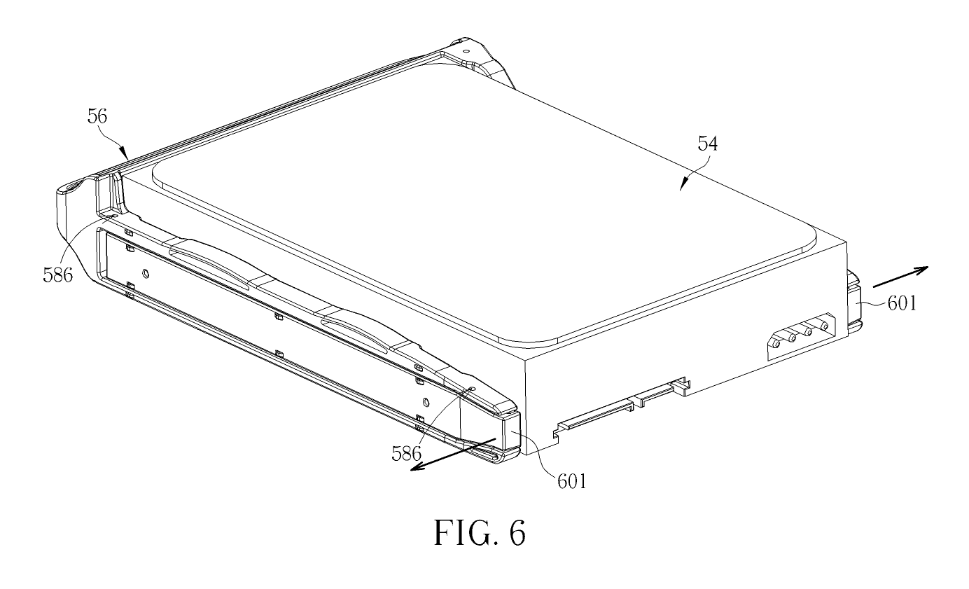

A procedure of installing the storage module 54 with the fixing mechanism 56 and installing an assembly of the storage module 54 and the fixing mechanism 56 inside the casing 52 is described as follows. Please refer to FIG. 1 to FIG. 6. FIG. 6 is an assembly diagram of the storage module 54 installed on the fixing mechanism 56 according to the embodiment of the present invention. First, the four resilient components 66 are installed on the two front holes 581 and the two rear holes 583, respectively. Because the four resilient components 66 are made of resilient material, and an outer diameter of each resilient component 66 is greater than a diameter of each front hole 581 and a diameter of each rear hole 583, the four inner portions 662 of the four resilient components 66 are pressed to deform inward by the two front holes 581 and the two rear holes 583 respectively as the four resilient components 66 are forced to install on the corresponding two front holes 581 and the corresponding two rear holes 583, so that the four inner portions 662 respectively pass through the corresponding two front holes 581 and the corresponding two rear holes 583. After the four inner portions 662 respectively pass through the corresponding two front holes 581 and the corresponding two rear holes 583, the four grooves 661 of the four resilient components 66 are respectively engaged with the corresponding two front holes 581 and the corresponding two rear holes 583, so as to fix the four resilient components 66 inside the two front holes 581 and the two rear holes 583.

Next, after the four locating holes 542 of the storage module 54 are aligned to the four locating columns 587 of the tray 58, the four locating columns 587 insert into the four locating holes 542, so that the storage module 54 is installed and located on the tray 58. Therefore, the six fixing holes 541 of the storage module 54 are aligned to the corresponding two front holes 581, the corresponding two middle holes 582 and the corresponding two rear holes 583. Then, the front fixing portion 641, the middle fixing portion 642, the rear fixing portion 643, the front engaging portion 621 and the rear engaging portion 622 of each fixing component 60 are respectively aligned to the corresponding front hole 581, the corresponding middle hole 582, the corresponding rear hole 583, the corresponding front engaging slot 584 and the corresponding rear engaging slot 585, and the two fixing components 60 are installed on the two sides of the tray 58 in an arrow direction shown in FIG. 2. At this time, the front fixing portion 641 inserts into a perforation 664 of the corresponding resilient component 66, the front hole 581 and the corresponding fixing hole 541 of the storage module 54. The middle fixing portion 642 inserts into the middle hole 582 and the corresponding fixing hole 541 of the storage module 54. The rear fixing portion 643 inserts into the perforation 664 of the corresponding resilient component 66, the rear hole 583 and the corresponding fixing hole 541 of the storage module 54. The front engaging portion 621 and the rear engaging portion 622 are respectively engaged with the front engaging slot 584 and the rear engaging slot 585. The protrusion 623 is engaged with the corresponding opening 586. Therefore, the procedure of installing the storage module 54 on the fixing mechanism 56 is finished. Finally, the storage module 54 and the fixing mechanism 56 are slidably installed on the track 523 in an arrow direction shown in FIG. 1 until the engaging component 521 is engaged with a front end of the fixing mechanism 56, so as to finish a procedure of installing the assembly of the storage module 54 and the fixing mechanism 56 inside the casing 52.

Furthermore, the fixing mechanism 56 further includes a detaching portion 601 for driving the corresponding engaging structure 62 to detach from the tray 58 and driving the corresponding fixing structure 64 to detach from the storage module 54 and the tray 58 as the detaching portion 601 is forced. As the user is desired to detach the storage module 54 from the fixing mechanism 56, the engaging component 521 can be detached from the fixing mechanism 56 first. Then, the storage module 54 and the fixing mechanism 56 are drawn out along the track 523 in a direction opposite to the arrow direction shown in FIG. 1. After that, the detaching portion 601 on a front end of each fixing component 60 is forced in an arrow direction shown in FIG. 6. Then, the front fixing portion 641 is detached from the perforation 664 of the corresponding resilient component 66, the front hole 581 and the corresponding fixing hole 541 of the storage module 54. The middle fixing portion 642 is detached from the middle hole 582 and the corresponding fixing hole 541 of the storage module 54. The rear fixing portion 643 is detached from the perforation 664 of the corresponding resilient component 66, the rear hole 583 and the corresponding fixing hole 541 of the storage module 54. The front engaging portion 621 and the rear engaging portion 622 are respectively detached from the front engaging slot 584 and the rear engaging slot 585. The protrusion 623 is detached from the corresponding opening 586. Finally, the two fixing components 60 are detached from the tray 58, and then the storage module 54 is separated from the tray 58.

In contrast to the prior art, the present invention provides the fixing mechanism for fixing the storage module on the tray. The front engaging portion and the rear engaging portion of the fixing component are respectively fixed on the front engaging slot and the rear engaging slot, and the front fixing portion, the middle fixing portion and the rear fixing portion of each fixing component respectively insert into the corresponding fixing holes of the storage module at the same time, so that the storage module is installed on the fixing mechanism. As a result, it improves the inconvenience in assembly by using the screws and the need of additional assembly tools, such as a screwdriver, to fix the storage module in the prior art. Therefore, the fixing mechanism of the present invention has enhanced convenience of assembly and has no additional manufacturing cost resulted from a complicated structural design. In addition, the fixing component is detachably installed on the tray, so that it can replace a new fixing component directly instead of replacing the whole fixing mechanism as the fixing component, the engaging structure or the fixing structure is damaged, so as to save the cost of components. Furthermore, as the storage module is detached from the tray, the fixing component and the resilient component can be installed on the tray again, so as to prevent the components from loss.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fixing mechanism, comprising:
a tray for supporting a storage module;
two fixing components detachably installed on two sides of the tray respectively;
two engaging structures disposed on the two fixing components respectively, the two engaging structures being for engaging the two fixing components with the tray; and
two fixing structures disposed on the two fixing components respectively, two fixing structures being for fixing the storage module on the tray after the two fixing components are engaged with the tray.

2. The fixing mechanism of claim 1, wherein each fixing structure comprises a front fixing portion, a middle fixing portion and a rear fixing portion for passing through a front hole, a middle hole and a rear hole respectively after the corresponding fixing component is engaged with the tray, to insert into a plurality of fixing holes on the storage module, so as to fix the storage module on the tray.

3. The fixing mechanism of claim 2, wherein each engaging structure comprises a front engaging portion and a rear engaging portion, and the front engaging portion and the rear engaging portion are engaged with a front engaging slot and a rear engaging slot of the tray respectively.

4. The fixing mechanism of claim 3, wherein the front hole and the rear hole are communicated to the front engaging slot and the rear engaging slot respectively.

5. The fixing mechanism of claim 3, wherein the middle fixing portion is a column whereon a slot is formed, and a size of the middle fixing portion is greater than a size of the corresponding fixing hole on the storage module, so that the middle fixing portion is deformed to engage with the storage module after passing through the corresponding fixing hole of the storage module.

6. The fixing mechanism of claim 3, wherein the front engaging portion and the rear engaging portion are hooks, respectively.

7. The fixing mechanism of claim 2, wherein at least one locating column is disposed on the tray for inserting into at least one locating hole on the storage module, so that the plurality of fixing holes is aligned to the corresponding front hole, the corresponding middle hole and the corresponding rear hole.

8. The fixing mechanism of claim 2, wherein the front fixing portion, the middle fixing portion and the rear fixing portion are pins, respectively.

9. The fixing mechanism of claim 1, further comprising four resilient components respectively disposed between the tray and the two fixing components, the four resilient components being respectively installed in the two front holes and the two rear holes, and the four resilient components being for contacting against the storage module to absorb shocks generated by the storage module as the two fixing structures fix the storage module on the tray.

10. The fixing mechanism of claim 9, wherein each resilient component comprises a groove, an inner portion and an outer portion, the four grooves of the four resilient components are engaged with the two front holes and the two rear holes respectively, and the four inner portions and the four outer portions of the four resilient components are located on two sides of the two front holes and the two rear holes respectively as the four grooves of the four resilient components are engaged with the two front holes and the two rear holes respectively, so as to contact against the two fixing components and the storage module respectively.

11. The fixing mechanism of claim 1, wherein each engaging structure comprises at least one protrusion, at least one opening is formed on the tray, and the at least one protrusion is engaged with the at least one opening, so that the corresponding fixing component is engaged with the tray.

12. The fixing mechanism of claim 1, wherein each fixing component comprises a detaching portion for driving the corresponding engaging structure to detach from the tray and driving the corresponding fixing structure to detach from the storage module and the tray as the detaching portion is forced.

13. An electronic device, comprising:
a casing whereon a track is disposed;
an engaging component disposed on a front end of the track;
a storage module installed inside the casing in a slidable manner relative to the track; and
a fixing mechanism for supporting the storage module and engaging with the engaging component after the storage module is installed inside the casing, so as to fix the storage module inside the casing, and the fixing mechanism comprising:
a tray for supporting the storage module;
two fixing components detachably installed on two sides of the tray respectively;
two engaging structures disposed on the two fixing components respectively, the two engaging structures being for engaging the two fixing components with the tray; and
two fixing structures disposed on the two fixing components respectively, two fixing structures being for fixing the storage module on the tray after the two fixing components are engaged with the tray.

14. The electronic device of claim 13, wherein each fixing structure comprises a front fixing portion, a middle fixing portion and a rear fixing portion for passing through a front hole, a middle hole and a rear hole respectively after the corresponding fixing component is engaged with the tray, to insert into a plurality of fixing holes on the storage module, so as to fix the storage module on the tray.

15. The electronic device of claim 14, wherein each engaging structure comprises a front engaging portion and a rear engaging portion, and the front engaging portion and the rear engaging portion are engaged with a front engaging slot and a rear engaging slot of the tray respectively.

16. The electronic device of claim 15, wherein the front hole and the rear hole are communicated to the front engaging slot and the rear engaging slot respectively.

17. The electronic device of claim 15, wherein the middle fixing portion is a column whereon a slot is formed, and a size of the middle fixing portion is greater than a size of the corresponding fixing hole of the storage module, so that the middle fixing portion is deformed to engage with the storage module after passing through the corresponding fixing hole of the storage module.

18. The electronic device of claim 15, wherein the front engaging portion and the rear engaging portion are hooks, respectively.

19. The electronic device of claim 14, wherein at least one locating column is disposed on the tray for inserting into at least one locating hole on the storage module, so that the plurality of fixing holes is aligned to the corresponding front hole, the corresponding middle hole and the corresponding rear hole.

20. The electronic device of claim 14, wherein the front fixing portion, the middle fixing portion and the rear fixing portion are pins, respectively.

21. The electronic device of claim 13, further comprising four resilient components respectively disposed between the tray and the two fixing components, the four resilient components being respectively installed in the two front holes and the two rear holes, and the four resilient components being for contacting against the storage module to absorb shocks generated by the storage module as the two fixing structures fix the storage module on the tray.

22. The electronic device of claim 21, wherein each resilient component comprises a groove, an inner portion and an outer portion, the four grooves of the four resilient components are engaged with the two front holes and the two rear holes respectively, and the four inner portions and the four outer portions of the four resilient components are located on two sides of the two front holes and the two rear holes respectively as the four grooves of the four resilient components are engaged with the two front holes and the two rear holes respectively, so as to contact against the two fixing components and the storage module respectively.

23. The electronic device of claim 13, wherein each engaging structure comprises at least one protrusion, at least one opening is formed on the tray, and the at least one protrusion is engaged with the at least one opening, so that the corresponding fixing component is engaged with the tray.

24. The electronic device of claim 13, wherein each fixing component comprises a detaching portion for driving the corresponding engaging structure to detach from the tray and driving the corresponding fixing structure to detach from the storage module and the tray as the detaching portion is forced.
